(19) United States
(12) Patent Application Publication
(10) Pub. No.: US 2026/0231549 A1
(43) Pub. Date: Aug. 6, 2026

(54) IMAGE SENSOR

(71) Applicant: SAMSUNG ELECTRONICS CO., LTD., Suwon-si (KR)

(72) Inventors: Minkyung LEE, Suwon-si (KR); Kooktae KIM, Suwon-si (KR); Jingyun KIM, Suwon-si (KR); Jehyung RYU, Suwon-si (KR); Byeongtaek BAE, Suwon-si (KR)

(73) Assignee: SAMSUNG ELECTRONICS CO., LTD., Suwon-si (KR)

(21) Appl. No.: 19/459,740

(22) Filed: Jan. 26, 2026

(30) Foreign Application Priority Data
Feb. 4, 2025 (KR) 10-2025-0013942

(51) Int. Cl. H10F 39/00; H10F 39/18

(52) U.S. Cl. CPC H10F 39/807; H10F 39/182; H10F 39/80373

(57) ABSTRACT

Provided is an image sensor including: a substrate including a first surface and a second surface, wherein the second surface is on an opposite side of the substrate from the first surface, and wherein the substrate includes a plurality of photodiode (PD) regions; and a PD isolation pattern in a PD isolation trench in the substrate, wherein the PD isolation trench separates the plurality of PD regions, wherein the PD isolation pattern includes: an insulating liner on an inner wall of the PD isolation trench; a crystalline semiconductor film on the insulating liner, the crystalline semiconductor film including a grain size of at least 100 nm; and a filling isolation layer on the crystalline semiconductor film, wherein the filling isolation layer fills the PD isolation trench.

### CROSS-REFERENCE TO RELATED APPLICATION

This application is based on and claims priority to Korean Patent Application No. 10-2025-0013942, filed on February 4, 2025, in the Korean Intellectual Property Office, the disclosure of which is incorporated herein by reference in its entirety.

### BACKGROUND

### 1. Field

The present disclosure relates to an image sensor and a method of manufacturing the same.

### 2. Description of Related Art

With recent advancements in the computing and telecommunications industries, the demand for high-performance image sensors has been increasing in various fields, including digital cameras, camcorders, personal communication systems (PCS), gaming devices, security cameras, and medical micro-cameras. An image sensor may be a device converting optical image signals into electrical signals. In particular, CMOS image sensors (CIS) may include a plurality of pixels arranged two-dimensionally. CISs may also have significantly lower power consumption, and thus may be applied to products with limited battery capacity. In addition, CISs may be manufactured using CMOS process technology, thereby reducing production costs. As a result, with continuous technological advancements enabling higher resolutions, the use of CISs has been rapidly expanding.

### SUMMARY

Provided is an image sensor having improved electrical and optical characteristics.

Further provided is a method of manufacturing an image sensor having improved electrical and optical characteristics.

According to an aspect of the disclosure, an image sensor includes: a substrate including a first surface and a second surface, wherein the second surface is on an opposite side of the substrate from the first surface, and wherein the substrate includes a plurality of photodiode (PD) regions; and a PD isolation pattern in a PD isolation trench in the substrate, wherein the PD isolation trench separates the plurality of PD regions, wherein the PD isolation pattern includes: an insulating liner on an inner wall of the PD isolation trench; a crystalline semiconductor film on the insulating liner, the crystalline semiconductor film including a grain size of at least 100 nm; and a filling isolation layer on the crystalline semiconductor film, wherein the filling isolation layer fills the PD isolation trench.

According to an aspect of the disclosure, an image sensor includes: a substrate including a first surface and a second surface, wherein the second surface is on an opposite side of the substrate from the first surface, and wherein the substrate includes a plurality of photodiode (PD) regions; a shallow trench isolation pattern on the first surface of the substrate, wherein the shallow trench isolation pattern defines an active region; a transfer gate on the active region; and a PD isolation pattern extending from the shallow trench isolation pattern to the second surface of the substrate, wherein the PD isolation pattern is in a PD isolation trench and defines the plurality of PD regions, wherein the PD isolation pattern includes: an insulating liner on an inner wall of the PD isolation trench; a crystalline semiconductor film on the insulating liner, the crystalline semiconductor film having a grain size of at least 100 nm; and a filling isolation layer on the crystalline semiconductor film, wherein the filling isolation layer fills the PD isolation trench.

According to an aspect of the disclosure, an image sensor includes: a substrate including a first surface and a second surface, wherein the second surface is on an opposite side of the substrate from the first surface, and wherein the substrate includes a plurality of photodiode (PD) regions; a transfer gate on an active region of the first surface of the substrate; and a PD isolation pattern in a PD isolation trench, the PD isolation pattern defining the plurality of PD regions, wherein the PD isolation trench extends from the second surface of the substrate toward the first surface of the substrate, and has a bottom positioned in a portion of the substrate adjacent to the first surface, and wherein the PD isolation pattern includes: an insulating liner on an inner wall and the bottom of the PD isolation trench; a crystalline semiconductor film on the insulating liner, the crystalline semiconductor film having a grain size of at least 100 nm; and a filling isolation layer on the crystalline semiconductor film, wherein the filling isolation layer fills the PD isolation trench.

According to an aspect of the disclosure, a method of manufacturing an image sensor includes: forming the photodiode (PD) isolation pattern on a substrate; forming a first isolation trench defining a pixel region on the substrate; sequentially forming an insulating liner and a polycrystalline semiconductor film in the first isolation trench; filling the first isolation trench with a filling isolation layer; forming a second isolation trench to expose the polycrystalline semiconductor film; forming a metal layer along surfaces of the polycrystalline semiconductor film exposed by the second isolation trench; crystallizing the polycrystalline semiconductor film using the metal layer through an annealing process; forming a desired first interlayer insulating layer by depositing an insulating material so as to fill the second isolation trench after a residual metal layer is removed, and performing a planarization process; and polishing the second surface of the substrate to expose the pixel isolation pattern after a first interconnection line structure is formed.

According to an aspect of the disclosure, a method of manufacturing an image sensor includes: forming a plurality of circuit devices on a first surface of a substrate; forming a PD isolation pattern on the substrate; forming a first isolation trench defining a pixel region on the substrate; sequentially forming an insulating liner and a polycrystalline semiconductor film in the first isolation trench; filling the first isolation trench with a filling isolation layer; forming a second isolation trench to expose the polycrystalline semiconductor film; forming a metal layer along a surface of the polycrystalline semiconductor film exposed by the second isolation trench; crystallizing the polycrystalline semiconductor film using the metal layer by applying an annealing process; forming a shallow trench isolation pattern by depositing an insulating material so as to fill the second isolation trench after a residual metal layer is removed; performing a planarization process; polishing the second surface of the substrate to expose the pixel isolation pattern after pixel circuit devices and a first interconnection line structure are formed.

### BRIEF DESCRIPTION OF DRAWINGS

The above and other aspects and features of the present disclosure will be more clearly understood from the following detailed description taken in conjunction with the accompanying drawings, in which:

FIG. 1 is an exploded perspective view of an image sensor according to an example embodiment of the present disclosure;

FIG. 2 is a plan view of portion “A” of the image sensor in FIG. 1;

FIG. 3 is a cross-sectional view of the image sensor in FIG. 2, taken along line I-I’;

FIG. 4 is an enlarged view of portion “A1” in FIG. 2;

FIG. 5 is an enlarged view of portion “B” in FIG. 3;

FIG. 6 is an enlarged view of portion “C1”in FIG. 5, as a side cross-sectional view of a photodiode (PD) isolation pattern according to an example embodiment of the present disclosure;

FIGS. 7A and 7B are graphs illustrating resistances and absorption coefficients of polycrystalline silicon and single-crystalline silicon, respectively;

FIG. 8 is a side cross-sectional view of a PD isolation pattern according to an example embodiment of the present disclosure;

FIGS. 9A, 9B, 9C, 9D, 9E, 9F and 9G are cross-sectional views of main processes in a method of manufacturing an image sensor according to an example embodiment of the present disclosure;

FIGS. 10A, 10B, 10C, 10D, 10E, 10F and 10G are cross-sectional views of main processes in a method of manufacturing an image sensor according to an example embodiment of the present disclosure;

FIG. 11A is a side cross-sectional view of an image sensor according to an example embodiment of the present disclosure;

FIG. 11B is an enlarged view of portion “C2” in FIG. 11A; and

FIG. 12 is a side cross-sectional view of a PD isolation pattern according to an example embodiment of the present disclosure.

### DETAILED DESCRIPTION

Hereinafter, various example embodiments of the present disclosure will be described in detail with reference to the accompanying drawings.

In the following description, like reference numerals refer to like elements throughout the specification.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

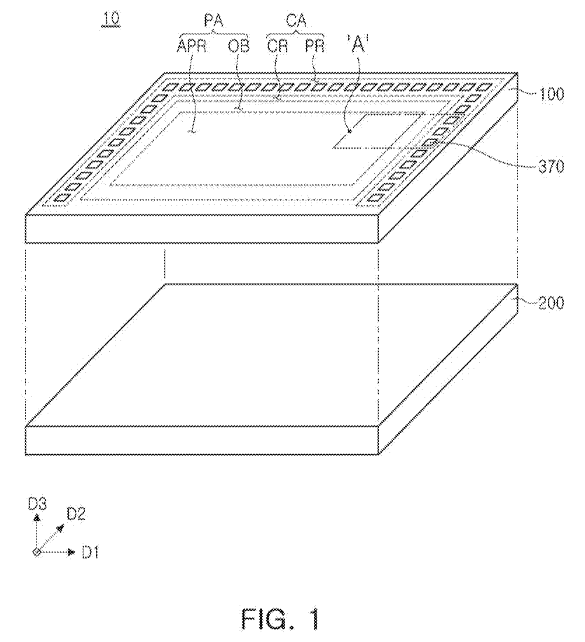

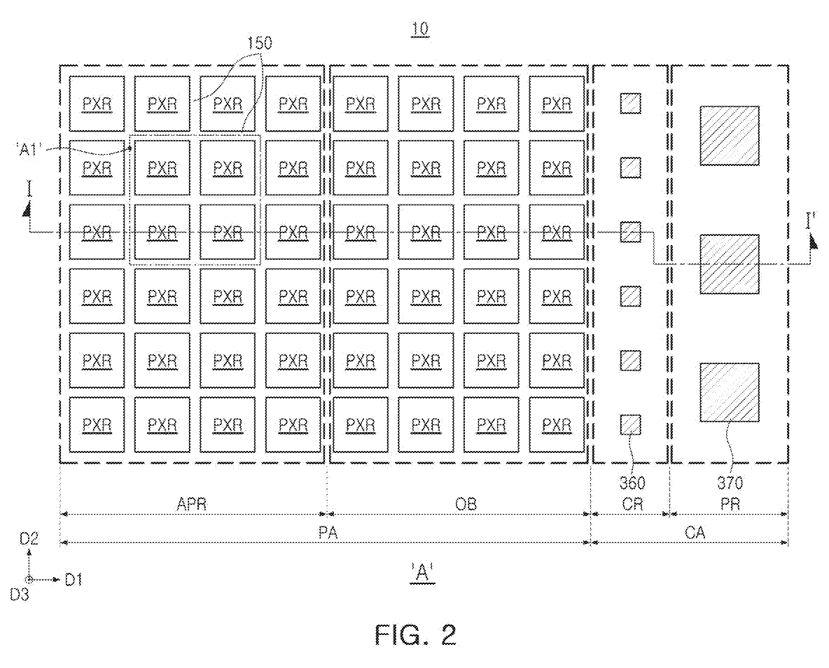

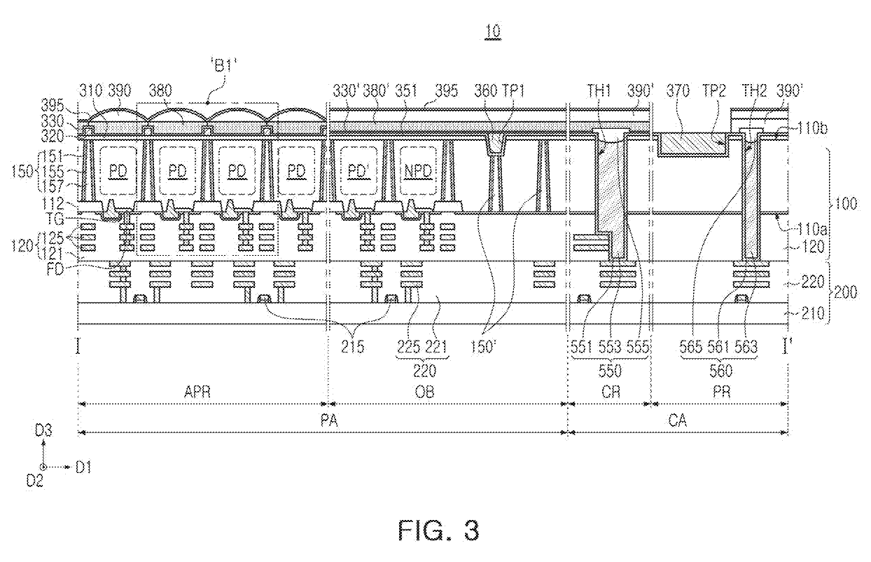

FIG. 1 is an exploded perspective view of an image sensor according to an example embodiment of the present disclosure. FIG. 2 is a plan view of portion “A” of the image sensor in FIG. 1, and FIG. 3 is a cross-sectional view of the image sensor in FIG. 2, taken along line I-I’.

Referring to FIGS. 1 to 3, an image sensor 10 according to the present example embodiment may include a stack structure having a first substrate structure 100 and a second substrate structure 200, electrically connected to each other.

The first substrate structure 100 may include a first substrate 110 having a pixel region PA, and a first interconnection line structure 120 on a first surface 110a of the first substrate 110. The second substrate structure 200 may include a second substrate 210 having an upper surface on which logic devices 215 are disposed, and a second interconnection line structure 220 in contact with the first interconnection line structure 120, on the second substrate 210. Here, the first substrate structure 100 may be referred to as a “sensor chip,” and the second substrate structure 200 is referred to as a “logic chip.”

In a plan view, the image sensor 10 according to the present example embodiment may include a pixel region PA in which a plurality of pixels PXR are two-dimensionally arranged, and a peripheral region CA positioned outside of the pixel region PA.

As illustrated in FIG. 1, the pixel region PA may include an active pixel region APR positioned at the center of the pixel region PA, and a light blocking region OB surrounding the active pixel region APR. Each of the active pixel region APR and the light blocking region OB may include a plurality of pixel regions PXR, receiving light and generating an electrical signal. The overall pixel regions PXR of the active pixel region APR may include an active pixel.

The light blocking region OB may be disposed around the active pixel array region APR. The light blocking region OB may include optical black pixels blocking light to generate an optical black signal. In one or more example embodiments, some pixels PXR (in particular, outer pixel regions) of the light blocking region OB may be dummy pixels.

The peripheral region PA may surround the pixel region PA, that is, the light blocking region OB. The peripheral region PA may include, for example, a connection region CR and a pad region PR. The connection region CR may be disposed to be adjacent to the light blocking region OB. In the present example embodiment, first connection structures 550, connecting the first substrate structure 100 and the second substrate structure 200 to each other, may be formed in the connection region CR (see FIG. 3).

The pad region PR may be disposed around the light blocking region OB. In one or more example embodiments, the pad region PR may be disposed to be adjacent to an edge of the image sensor 10. In the present example embodiment, it is illustrated that the pad region PR is disposed along three sides of the image sensor 10. However, in one or more example embodiments, the pad region PR may be disposed to surround two sides or all sides. The pad region PR may include a plurality of external bonding pads 370 for connection to an external device, and may be configured to transmit and receive an electrical signal between the image sensor 10 and the external device.

As described above, referring to FIG. 3, the image sensor 10 according to the present example embodiment may include a stack structure having a first substrate structure 100 and a second substrate structure 200. The image sensor according to the present example embodiment is illustrated as a stack structure having two substrates, but the present disclosure is not limited thereto. In one or more example embodiments, the image sensor may include a stack structure having three substrates. For example, at least one transistor of transistors for a pixel circuit may be implemented on an intermediate substrate instead of the first substrate 110.

Referring to FIG. 3, the first substrate 110 according to the present example embodiment may include a shallow trench isolation pattern 112, defining an active region ACT, on the first surface 110a, and pixel circuit devices such as a vertical transfer gate TG on the active region. A plurality of photodiode (PD) regions (or photoelectric conversion element regions) may be disposed in the substrate 110.

The plurality of pixels PXR may be regions, externally receiving light and converting light into an electrical signal. For example, each of the plurality of pixels PXR may include a photodiode for receiving external light, and transistors included in a pixel circuit for converting photocharges accumulated in the photodiode PD into electrical signals.

The first substrate 110 may be a semiconductor substrate. For example, the first substrate 110 may be a bulk silicon or a silicon-on-insulator (SOI) substrate. The plurality of pixels PXR may be arranged in the pixel region PA in a planar manner, that is, in a first direction D1 and a second direction D2, and may be defined by a photodiode (PD) isolation pattern 150. Each pixel PXR may include at least one photodiode region PD disposed in the first substrate 110. The photodiode region PD may generate electric charges in proportion to an amount of externally incident light. For example, the photodiode PD may be a various type of photo diodes, such as a photo transistor, a photo gate, a pinned photo diode, or an organic photo diode.

As described above, the photodiode regions PD may be disposed in the light blocking region OB in addition to the active pixel region APR provided as an active pixel. In the light blocking region OB, a first reference region PD’ configured to be the same as or similar to the photodiode regions PD, and a second reference region NPD that is not included in the photodiode region PD may be provided. In the light blocking region OB, the first and second reference regions PD’ and NPD may be disposed in the first substrate 110, and may be isolated from each other by the PD isolation pattern 150.

The image sensor 10 according to the present example embodiment may be a backside-illuminated (BSI) image sensor. A second surface 110b of the first substrate 110 may be provided as a light-receiving surface on which light is incident. In the active pixel region APR and the light blocking region OB, the first substrate 110 may further include a PD isolation pattern 150 defining unit pixels, that is, the plurality of pixels PXR. The PD isolation pattern 150 may be configured to pass through the first substrate 110, thereby preventing crosstalk between adjacent pixels caused by obliquely incident light.

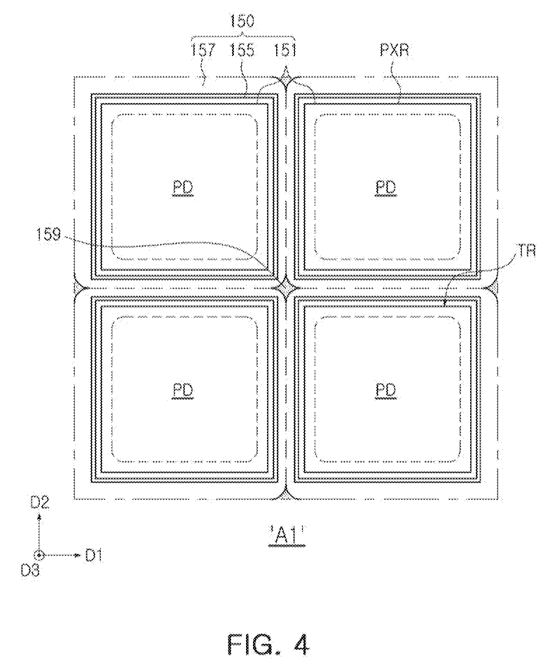

Referring to FIGS. 2 and 4, in a plan view, the PD isolation pattern 150 may be formed in a lattice shape to define the plurality of pixels PXR. In the present example embodiment, the PD isolation pattern 150 may be provided in a photodiode (PD) isolation trench TR extending from the first surface 110a to the second surface 110b of the first substrate 110. The PD isolation pattern 150 may be configured to pass through the substrate 100. The PD isolation pattern 150 may pass through one region of the shallow trench isolation pattern 112. A length (or a thickness) of the PD isolation pattern 150 in a third direction D3 may be substantially the same as a thickness of the substrate 110.

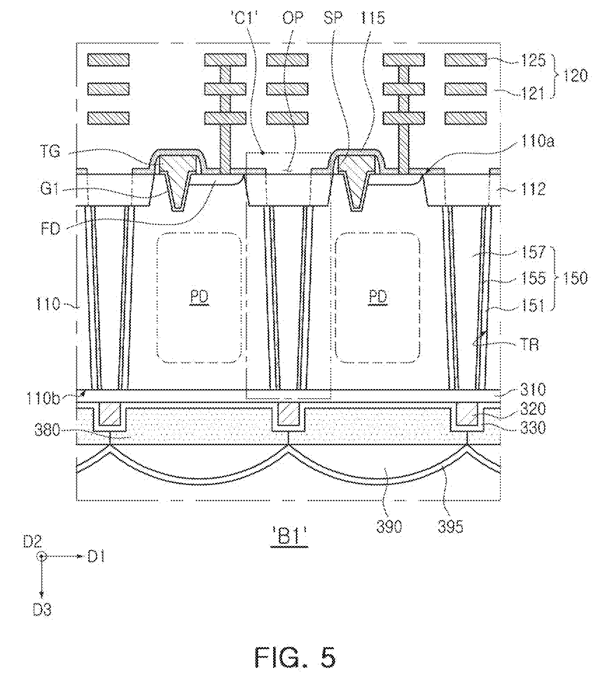

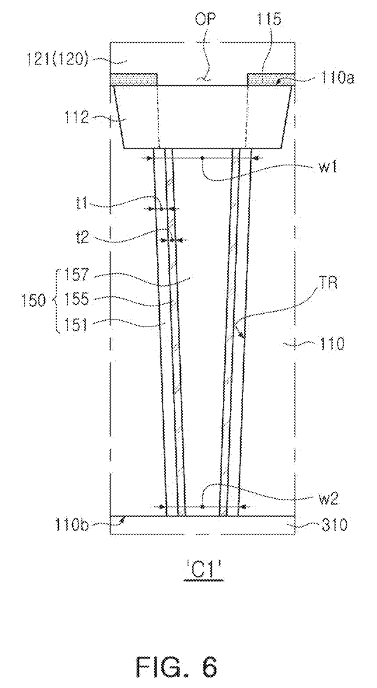

Referring to FIGS. 5 and 6, the PD isolation pattern 150 may have a first width w1, on the first surface 110a of the substrate 110, and a second width w2, on the second surface 110b of the substrate 110, and the second width w2 may be less than the first width w1. For example, a width of the PD isolation pattern 150 may gradually decrease from the first surface 110a to the second surface 110b of the substrate 110.

The PD isolation pattern 150 may include an insulating liner 151, a crystalline semiconductor film 155, and a filling isolation layer 157. The PD isolation pattern 150 will be described in detail with reference to FIGS. 4 to 6.

FIG. 4 is an enlarged view of portion “A1” in FIG. 2, and FIG. 5 is an enlarged view of portion “B” in FIG. 3. FIG. 6 is an enlarged view of portion “C1”in FIG. 5, as a side cross-sectional view of a PD isolation pattern according to an example embodiment of the present disclosure.

Referring to FIGS. 4 to 6, the insulating liner 151 may be disposed on an inner wall of the PD isolation trench TR, and may be in contact with the exposed substrate 110 of the PD isolation trench TR. The crystalline semiconductor film 155 may be disposed on the insulating liner 151 along the inner wall of the PD isolation trench TR. The crystalline semiconductor film 155 may be in contact with the insulating liner 151. The crystalline semiconductor film 155 may be provided as a conductive film. The PD isolation pattern 150 may further include a filling isolation layer 157 disposed on the crystalline semiconductor film 155 to fill the PD isolation trench TR.

The crystalline semiconductor film 155 may include a semiconductor material doped with impurities. For example, the crystalline semiconductor film 155 may include silicon doped with first conductivity-type (for example, P-type) impurities, the same as those of the substrate 110. However, the present disclosure is not limited thereto. In one or more example embodiments, the crystalline semiconductor film 155 may be silicon germanium or germanium.

The crystalline semiconductor film 155 according to the present example embodiment may have single crystallinity, or crystallinity close to single crystallinity rather than polycrystallinity. The crystalline semiconductor film 155 may have a grain size of at least 100 nm. A grain boundary of the crystalline semiconductor film 155 may be observed in a thickness direction D3 of the PD isolation pattern 150 (see FIG. 6), or may be observed in a horizontal direction D1 or D2 in a plan view (see FIG. 4).

The crystalline semiconductor film 155 according to the present example embodiment may have physical properties different from those of a polycrystalline semiconductor according to the related art (for example, 50 nm or less). The crystalline semiconductor film 155 may have a resistance and a light absorption coefficient lower than those of the polycrystalline semiconductor.

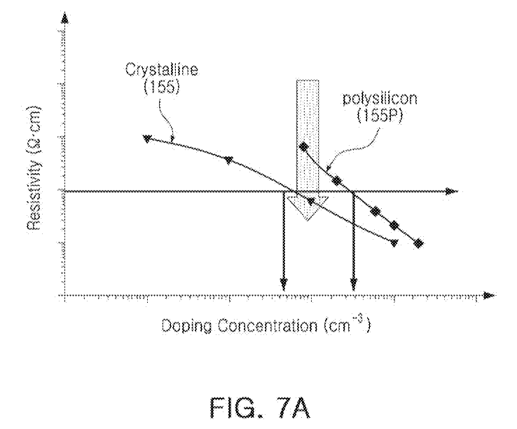

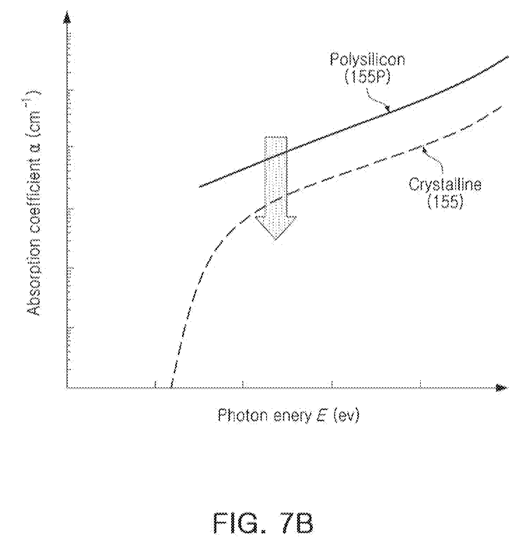

FIGS. 7A and 7B are graphs illustrating resistances and absorption coefficients of polycrystalline silicon and single-crystalline silicon, respectively.

Referring to FIG. 7A, single-crystalline silicon may have a resistance, the same as polycrystalline silicon even with relatively low impurity doping. That is, single-crystalline silicon may have a resistance lower than that of polycrystalline silicon under the same impurity doping conditions. As described above, the crystalline semiconductor film 155 having improved crystallinity may be expected to have electrical conductivity higher than that of the polycrystalline semiconductor according to the related art.

Referring to FIG. 7B, single-crystalline silicon may have a light absorption coefficient relatively lower than that of polycrystalline silicon under light having the same photon energy, and polycrystalline silicon may have a localized energy level (trap state) generated due to defects, and thus may tend to absorb a broader range of photon energies compared to single-crystalline silicon. As described above, the crystalline semiconductor film 155 having improved crystallinity may be expected to exhibit a light absorption coefficient lower than that of the polycrystalline semiconductor according to the related art.

The crystalline semiconductor film 155 according to the present example embodiment may have a resistance and a light absorption coefficient lower than those of the polycrystalline semiconductor. Accordingly, the crystalline semiconductor film 155 may provide a conductive path having sufficient conductivity while ensuring low optical loss due to absorption.

In one or more example embodiments, a thickness t2 of the crystalline semiconductor film 155 may be less than a thickness t1 of the insulating liner 151. The thickness t2 of the crystalline semiconductor film 155 may be within a range of 20 Å to 370 Å. In one or more example embodiments, in order to further lower a light absorption rate, the thickness t2 of the crystalline semiconductor film 155 may be within a range of 100 Å or less.

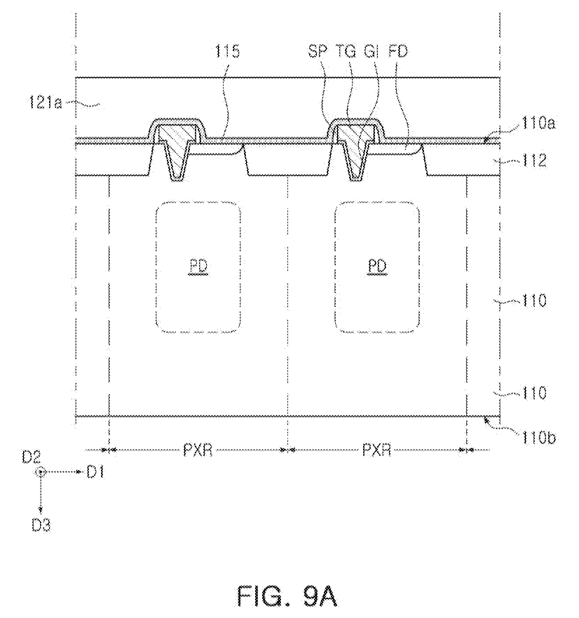

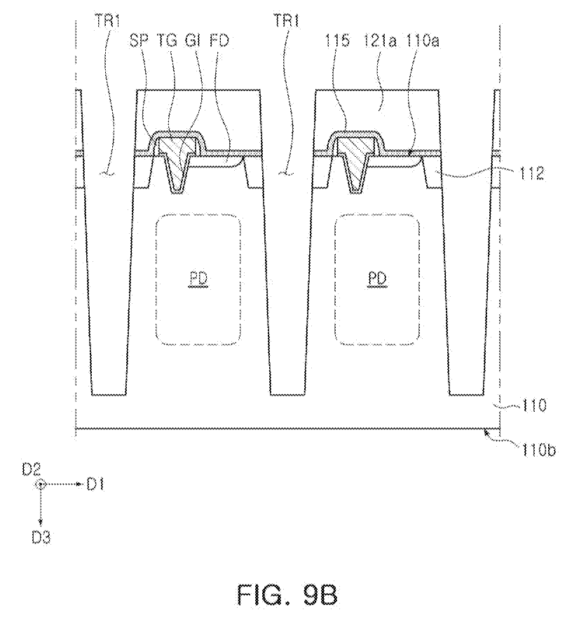

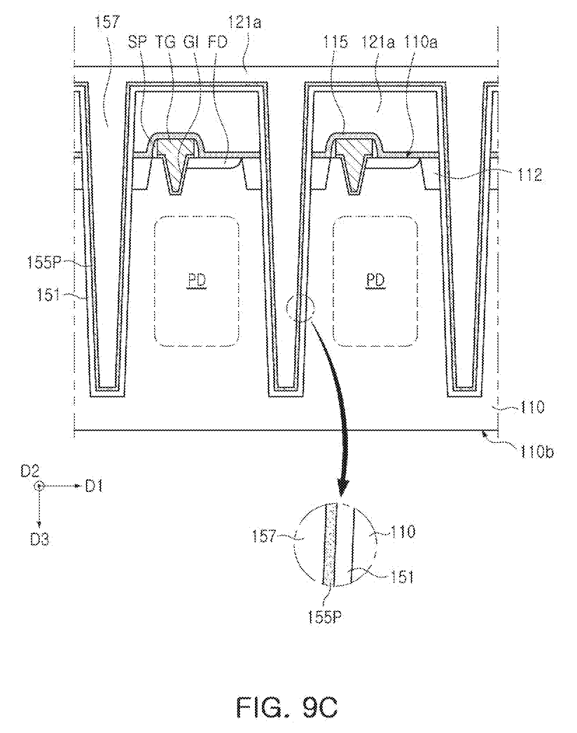

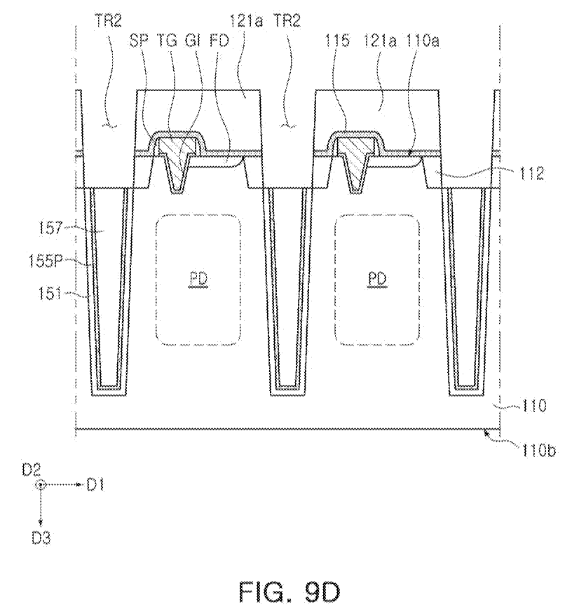

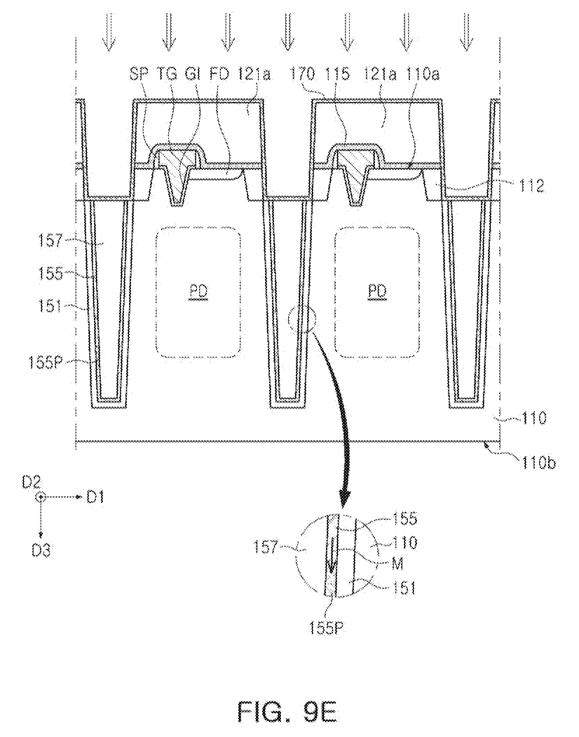

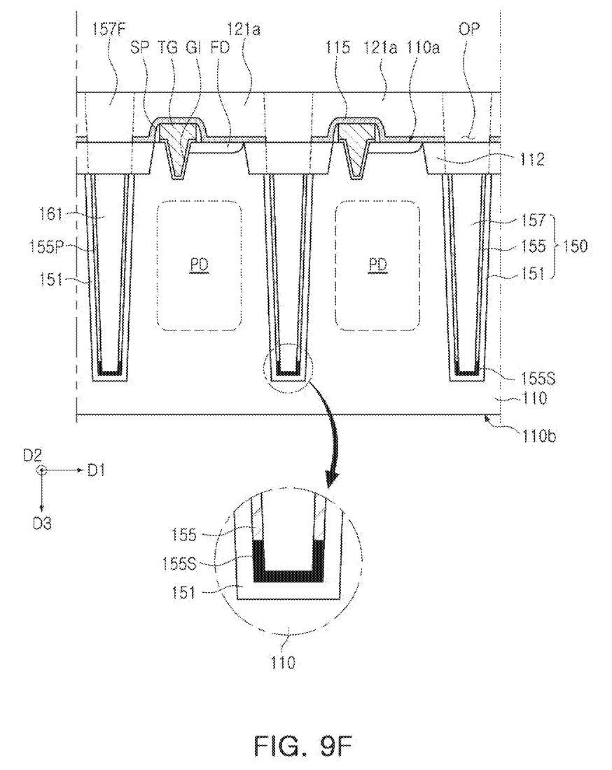

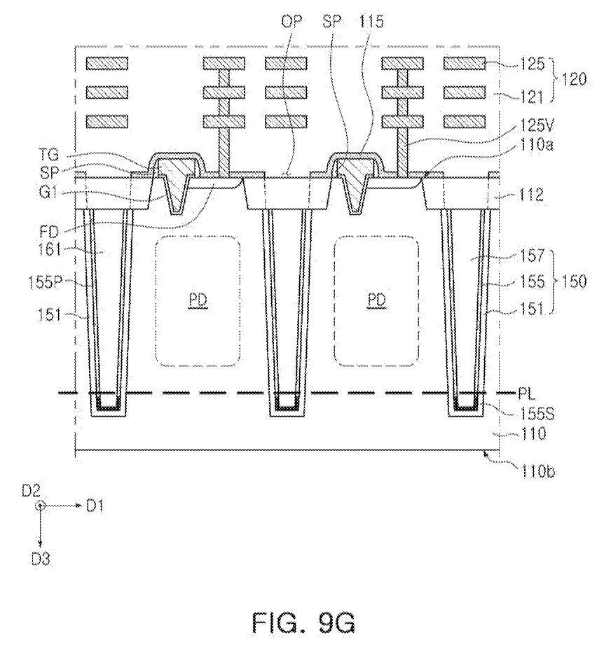

The crystalline semiconductor film 155 may be formed by forming an amorphous or polycrystalline semiconductor film and then crystallizing the amorphous or polycrystalline semiconductor film using metal-induced crystallization (MIC) (see FIG. 9E). The crystalline semiconductor film 155 may include a metal element used for MIC in an amount of 2 at% or less. For example, the crystalline semiconductor film 155 may include Ni, Pd, Al, Ag, Cu, or Sn.

The insulating liner 151 may include a silicon-based insulating material (for example, silicon nitride, silicon oxide, and/or silicon oxynitride), a high-κ material (for example, hafnium oxide and/or aluminum oxide), and/or a metal oxide. The filling isolation layer 157 may include an insulating material the same as or similar to that of the insulating liner 151.

In one or more example embodiments, the filling isolation layer 157 may include two or more layers. Referring to FIG. 4, the PD isolation pattern 150 may further include a filling unit 159 for charging an empty space between corners of four pixels. The filling unit 159 may include the above-described insulating material or a conductive material such as polysilicon.

Referring to FIGS. 5 and 6, the shallow trench isolation pattern 112 may be disposed on the first surface 110a of the substrate 110 to define an active region. The crystalline semiconductor film 155 may extend from below the shallow trench isolation pattern 112 to the second surface 110b of the substrate 110.

In one or more example embodiments, a portion of the crystalline semiconductor film 155, adjacent to the first surface 110a, may include a metal-semiconductor compound. For example, the metal-semiconductor compound may include a metal silicide. The metal of the metal silicide may be the same metal as the metal element contained in the crystalline semiconductor film 155.

Referring to FIGS. 3 and 5, various pixel circuit devices, such as the gate TG, may be formed on the active region on the first surface 110a of the substrate 110. The active region may include an adjacent floating diffusion region FD of the transfer gate TG. The transfer gate TG may be a vertical transfer gate. The transfer gate TG may include a gate insulating film GI and a gate spacer SP. The gate insulating film GI may be disposed between the transfer gate TG and the substrate 100, and the gate spacer SP may be disposed on a side surface of the transfer gate TG.

The cover insulating film 115 may be disposed on the first surface 110a of the substrate 110 to cover the transfer gate TG. The cover insulating film 115 may be provided as an etching stop layer for forming a contact via 125V (see, e.g., FIG. 9G). For example, the cover insulating film 115 may include silicon nitride, silicon oxynitride, or silicon carbide. In the present example embodiment, the cover insulating film 115 may have the opening OP of which an area corresponding to the PD isolation pattern 150 is opened. The opening OP may be understood to be a result of a process of forming the crystalline silicon film 155 after various pixel circuit devices are formed on the first surface 110a of the substrate 110 (see, e.g., FIGS. 9A to 9G).

The first interconnection line structure 120 may include a first inter-interconnection line insulating layer 121, and a plurality of first interconnection lines 125 on the first inter-interconnection line insulating layer 121. The number and arrangement of layers of interconnection lines, included in the first interconnection line structure 120, illustrated in the drawings are merely exemplary. For example, the first inter-interconnection line insulating layer 121 may include at least one of silicon oxide, silicon nitride, silicon oxynitride, or a low-κ material having a dielectric constant lower than that of silicon oxide. For example, the first interconnection lines 125 may include at least one of tungsten (W), copper (Cu), aluminum (Al), gold (Au), silver (Ag), or alloys thereof.

In a similar manner to the first substrate 110, the second substrate 210 may be a bulk silicon or a SOI substrate. Logic devices 215 may be disposed on the second substrate 210. The logic devices 215 may provide a constant signal to each pixel PX of the active pixel region APR or may be included in a circuit controlling an output signal in each unit pixel. For example, the logic devices 215 may include various transistors included in a control register block, a timing generator, a ramp signal generator, a row driver, a readout circuit, and/or an I/O buffer circuit.

The second interconnection line structure 220 may be disposed between the first interconnection line structure 120 of the first substrate structure 100 and the second substrate 210. The second interconnection line structure 220 may include a second inter-interconnection line insulating layer 221 and a plurality of second interconnection lines 225 on the second inter-interconnection line insulating layer 221. The number and arrangement of layers of interconnection lines included in the second interconnection line structure 220 are merely exemplary. The plurality of second interconnection lines 225 may include vias electrically connecting the logic devices 215 to each other. For example, the second inter-interconnection line insulating layer 221 may include at least one of silicon oxide, silicon nitride, silicon oxynitride, or silicon oxide, and a low-κ material having a dielectric constant lower than that of silicon oxide. The second interconnection lines 225 may include, for example, at least one of tungsten (W), copper (Cu), aluminum (Al), gold (Au), silver (Ag), or alloys thereof.

In the present example embodiment, the first interconnection line structure 120 may be bonded to the second interconnection line structure 220. In one or more example embodiments, each of the first and second interconnection line structures 120 and 220 may include a bonding insulating layer disposed on a surface thereof to be bonded. In addition, the first and second substrate structures 100 and 200 may be coupled to each other by first and second connection structures 550 and 560 passing through the first substrate structure 100, the first and second connection structures 550 and 560 connected to the second substrate structure 200. The first and second connection structures 550 and 560 may be disposed in the connection region CR and the pad region PR, respectively, and may electrically connect a first interconnection line 125 and a second interconnection line 225 to each other.

Referring to FIG. 3, the first substrate structure 100 may include an anti-reflection layer 310 formed on the second surface 110b of the first substrate 110. The anti-reflection layer 310 may serve to suppress reflection of incident light and increase an amount of light incident on the photodiode region PD. The anti-reflection layer 310 may be disposed in the entire pixel region PA, but may be selectively disposed in the peripheral region CA. For example, the anti-reflection layer 310 may not be disposed on a rear contact 360, the first connection structure 550, the second connection structure 560, and an external bonding pad 370.

In the pixel region PA, the first substrate structure 100 may include a grid pattern 320 on the anti-reflection layer 310, a first protective layer 330 covering the anti-reflection layer 310 and the grid pattern 320, a color filter layer 380 isolated by the grid pattern 320, and microlenses 390 on the color filter layer 380.

The grid pattern 320 may have a lattice shape from a plan view, and may vertically overlap the PD isolation pattern 150 in the active pixel region APR. In one or more example embodiments, the grid pattern 320 may include a conductive pattern. The conductive pattern may prevent ESD defects. The conductive pattern may include, for example, at least one of titanium (Ti), titanium nitride (TiN), tantalum (Ta), tantalum nitride (TaN), tungsten (W), aluminum (Al), or copper (Cu). In one or more example embodiments, the grid pattern 320 may include a low refractive index pattern. The low refractive index pattern may improve light-condensing efficiency by refracting or reflecting obliquely incident light, thereby improving the quality of the image sensor. The low refractive index pattern may include a low refractive index material having a refractive index lower than that of silicon (Si). For example, the low refractive index pattern may include at least one of silicon oxide, aluminum oxide, tantalum oxide, or a combination thereof.

The first protective layer 330 may be conformally formed along an upper surface of the anti-reflection layer 310 and a side surface and an upper surface of the grid pattern 320. The first protective layer 330 may prevent damage to the grid pattern 320. For example, the first protective layer 330 may include at least one of silicon oxide, silicon nitride, silicon oxynitride, aluminum oxide, hafnium oxide, or a combination thereof.

The color filter layer 380 may be disposed between the grid patterns 320, on the anti-reflection layer 310. The color filter layer 380 may be arranged to correspond to each unit pixel of the active pixel region APR. The color filter layer 380 may have various color filters depending on the unit pixel. For example, the color filter layer 380 may include a red color filter, a green color filter, and a blue color filter. In one or more example embodiments, the color filter layer 380 may be arranged in a Bayer pattern. However, such a configuration is merely exemplary, and the color filter layer 380 may include a yellow filter, a magenta filter, and a cyan filter, and may further include a white filter.

The microlens layer 390 may be disposed on the color filter layer 380. The microlens layer 390 may include microlenses arranged to correspond to respective unit pixels of the pixel array region PA. Each of the microlenses may have a convex shape, and may have a predetermined radius of curvature. Accordingly, the microlenses may condense light incident on the photodiode regions PD. The microlens layer 390 may include, for example, a light-transmissive resin. In one or more example embodiments, the microlens layer 390 may extend to a portion (for example, the light blocking region OB) of the peripheral region.

Referring to FIG. 3, in the light blocking region OB, a first conductive layer 551, a first protective layer 330, and a light blocking filter layer 380’ may be disposed on the anti-reflection layer 310. In one or more example embodiments, the light blocking filter layer 380’ may extend from the light blocking region OB to the connection region CR on the first conductive layer 551, and may be provided as a light blocking structure blocking light together with the first conductive layer 551. The light blocking filter layer 380’ may be formed together with the color filter layer 380 to have a thickness substantially the same as that of the color filter layer 380, but the present disclosure is not limited thereto. The light blocking filter layer 380’ may include a blue color filter or a black filter.

In one or more example embodiments, the light blocking region OB may be used to remove a noise signal caused by dark current. For example, in a state in which light is blocked by the first conductive layer 551 and the light blocking filter layer 380’, a first reference region PD’ including a photodiode may be used as a reference pixel for noise removal caused by the photodiode. In addition, in a state in which light is blocked by the first conductive layer 551 and the light blocking filter layer 380’, a second reference region NPD, not including a photodiode, may be used as a region for checking process noise for noise removal, caused by components other than the photodiode.

A rear contact 360 may be disposed in the light blocking region OB. The rear contact 360 may fill a first trench TP1. The rear contact 360 may include a metal material (for example, aluminum). The rear contact 360 may be connected to the PD isolation pattern 150. A bias may be applied to the conductive material 155 of the PD isolation pattern 150 through the rear contact 360. In addition, the first conductive layer 551 may be connected to the PD isolation pattern 150. The first conductive layer 551 may include a metal material (for example, tungsten). As described above, the first conductive layer 551 may block light incident in the light blocking region OB.

A first connection structure 550 may be disposed in the connection region CR. The first connection structure 550 may include a first conductive layer 551, a first isolation pattern 553, and a first capping pattern 555. The first conductive layer 551 may conformally extend to an inner wall of a first through-hole TH1 on the second surface 110b of the first substrate 110. The first conductive layer 551 may pass through the first substrate 110 and the first interconnection line structure 120, that is, the first substrate structure 100, so as to connect a first interconnection layer 125 and a second interconnection layer 225 to each other.

The second connection structure 560 and an external bonding pad 392 may be disposed in the pad region PR. The second connection structure 560 may include a second conductive layer 561, a second isolation pattern 563, and a second capping pattern 565. The second conductive layer 561 may be formed on the second surface 110b of the first substrate 110 to cover the anti-reflection layer 310. The second conductive layer 561 may conformally cover an inner wall of a second through-hole TH2. The second conductive layer 561 may pass through the first substrate 110 and the first interconnection line structure 120, that is, the first substrate structure 100, so as to connect the first interconnection line layer 125 and the second interconnection line layer 225 to each other. The second conductive layer 561 may include a metal material (for example, tungsten) in a similar manner to the first conductive layer 551.

The external bonding pad 370 may fill a second trench TP2. The external bonding pad 370 may include a metal material (for example, aluminum). The external bonding pad 370 may serve as an electrical connection path between the image sensor 10 and the external device. The external bonding pad 370 may be connected to the logic devices 215 of the second substrate 210 through the second conductive layer 561 of the second connection structure 560 and the second interconnection line layer 225. An electrical signal generated in the photodiode regions PD of the pixel array region PA may be transmitted to the external device through the first and second interconnection line layers 125 and 225, the second conductive layer 561, and the external bonding pad 370.

Referring to FIG. 3, a transparent planarization layer 390’ may be formed in the light blocking region OB, the connection region CR, and the pad region PDR. The transparent planarization layer 390’ may provide a flat upper surface while covering the light blocking filter layer 380’ and the second connection structures 560, on the second surface 110b of the first substrate 110.

The transparent planarization layer 390’ may include a light-transmissive inorganic material. In one or more example embodiments, the transparent planarization layer 390’ may include an oxide such as tetraethyl ortho silicate (TEOS), but the present disclosure is not limited thereto. The transparent planarization layer 390’ may include spin-on hardmask (SOH), flowable oxide (FOX), tonen silaZen (TOSZ), undoped silica glass (USG), borosilica glass (BSG), phosphosilica glass (PSG), borophosphosilica glass (BPSG), plasma-enhanced tetraethyl orthosilicate (PETEOS), fluoride silicate glass (FSG), high-density plasma (HDP) oxide, plasma-enhanced oxide (PEOX), flowable chemical vapor deposition (FCVD) oxide, or combinations thereof. The transparent planarization layer 390’ may be formed to have a flat upper surface using a chemical vapor deposition process, a fluid CVD process, or a spin coating process. The transparent planarization layer 390’ may include a material, the same as that of the microlens layer 390.

The second protective layer 395 may be disposed on the microlens layer 390. The second protective layer 395 may extend along a surface of the microlens layer 390. The second protective layer 395 may externally protect the microlens layer 390. For example, the second protective layer 395 may include an inorganic oxide film to protect the microlens 390 including an organic material. In addition, the second protective layer 395 may improve light-condensing efficiency of the microlens layer 390, thereby improving the quality of the image sensor. The second protective layer 395 may include, for example, an inorganic oxide film such as silicon oxide, titanium oxide, zirconium oxide, hafnium oxide, or a combination thereof. In one or more example embodiments, the second protective layer 395 may include low-temperature oxide (LTO).

In the image sensor 10 according to the present example embodiment, the PD isolation pattern 150 may include a crystalline semiconductor film 155 having single crystallinity or crystallinity close thereto (for example, a grain size of 100 nm or less). Accordingly, even when the PD isolation pattern 150 has a small thickness to lower light absorption by the PD isolation pattern 150, the PD isolation pattern 150 may ensure sufficient electrical conductivity.

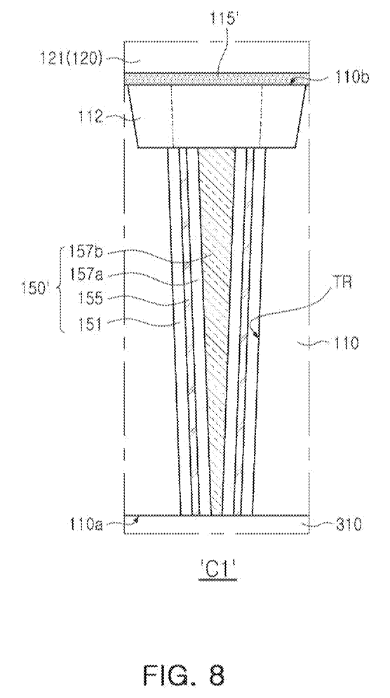

FIG. 8 is a side cross-sectional view of a PD isolation pattern according to an example embodiment of the present disclosure. The cross-section in FIG. 8 may be understood as a portion corresponding to C1 in FIG. 3 in a similar manner to the cross-section in FIG. 6.

Referring to FIG. 8, a PD isolation pattern 150’ according to the present example embodiment may include an insulating liner 151, a crystalline semiconductor film 155, and filling isolation layers 157a and 157b having a multilayer structure in a similar manner to the PD isolation pattern 150 according to the previous example embodiment.

The insulating liner 151 may be disposed on the inner wall of the PD isolation trench TR, and the crystalline semiconductor film 155 may be disposed on the insulating liner 151 along the inner wall of the PD isolation trench TR. The crystalline semiconductor film 155 according to the present example embodiment may have single crystallinity, rather than crystallinity, or crystallinity close to the single crystallinity. The crystalline semiconductor film 155 may have a grain size of at least 100 nm. The crystalline semiconductor film 155 according to the present example embodiment may have a resistance and a light absorption coefficient, lower than those of the polycrystalline semiconductor.

The filling isolation layers 157a and 157b having a multilayer structure may include a first isolation layer 157a disposed on the crystalline semiconductor film 155 to fill the PD isolation trench TR, and a second isolation layer 157b disposed on the first isolation layer 157a. The first isolation film 157a and the second isolation film 157b may include different material films. For example, the first isolation film 157a and the second isolation film 157b may include a silicon-based insulating material (for example, silicon nitride, silicon oxide, and/or silicon oxynitride), a high-κ material (for example, hafnium oxide and/or aluminum oxide), and/or metal oxide in a similar manner to the insulating liner 151.

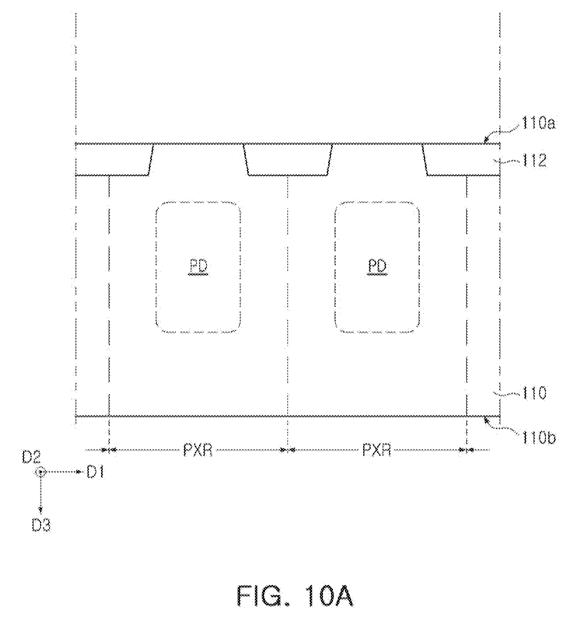

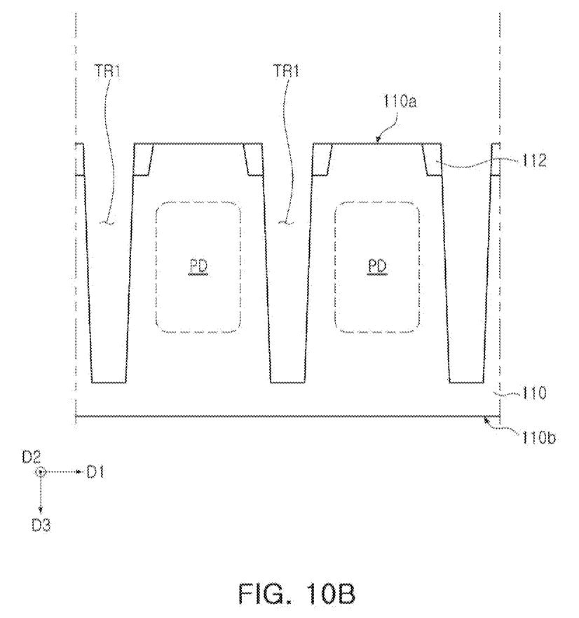

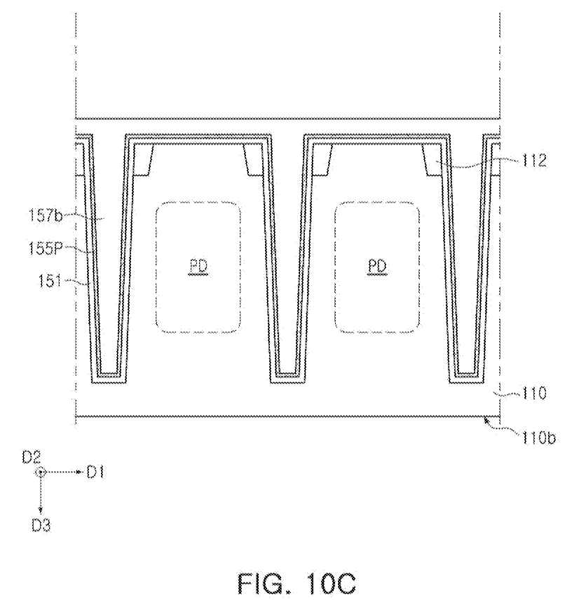

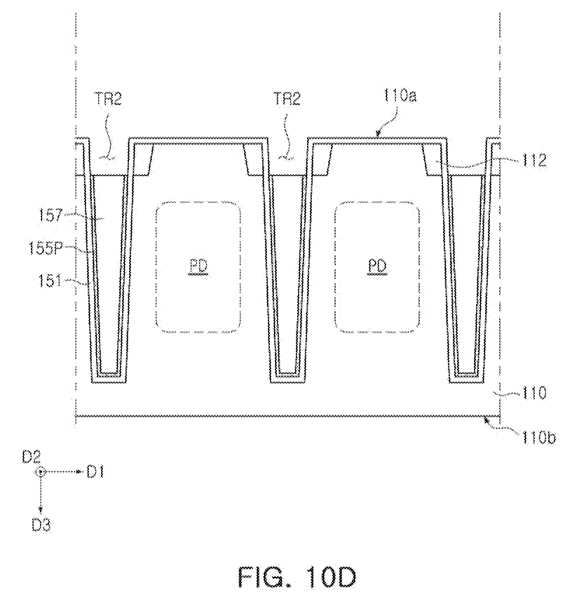

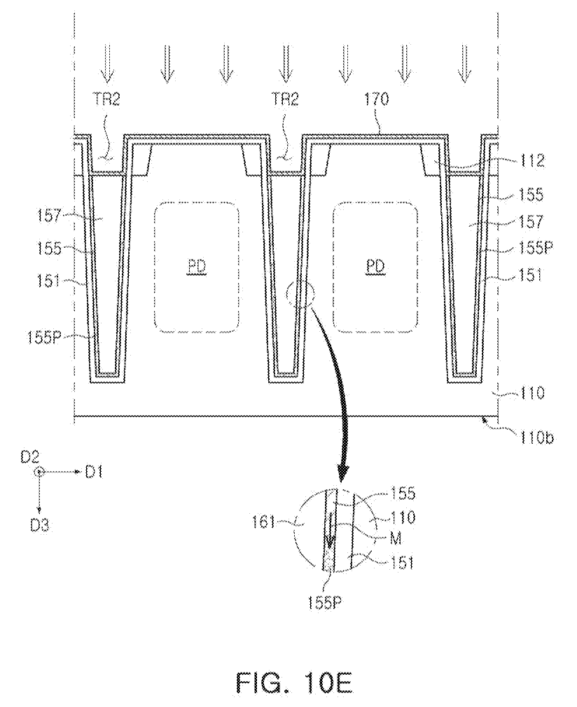

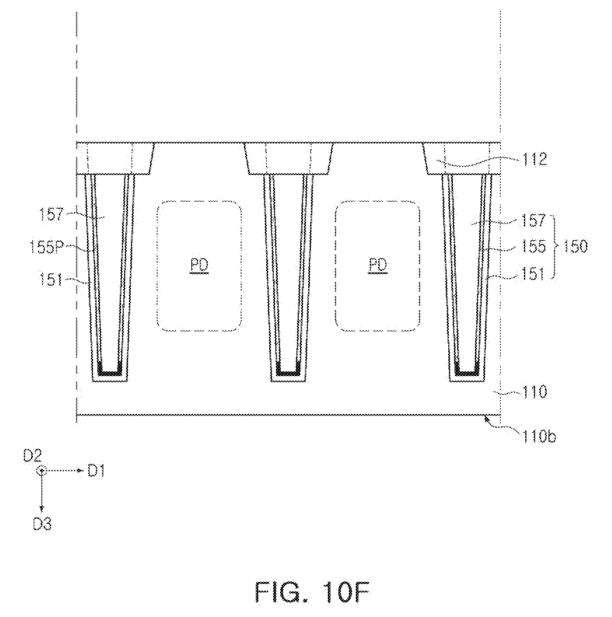

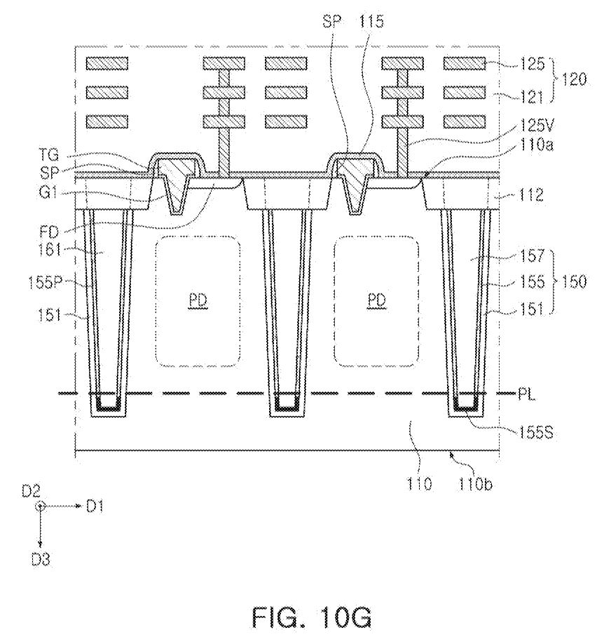

In the present example embodiment, a cover insulating film 115’ may be formed to cover the PD isolation pattern 150 without an opening unlike the previous example embodiment. It may be understood as a result of a process of forming the PD isolation pattern 150 having the crystalline silicon film 155 before forming various pixel circuit devices on the first surface 110a of the substrate 110 (see FIGS. 10A to 10G).

FIGS. 9A to 9G are cross-sectional views of main processes in a method of manufacturing an image sensor according to an example embodiment of the present disclosure. The processes may be a process of forming a PD isolation pattern 150 in the method of manufacturing the image sensor 10 illustrated in FIGS. 3 to 6, and the cross-section in FIGS. 9A to 9G may be understood as a cross-section corresponding to the cross-section in FIG. 6.

First, referring to FIG. 9A, the process of forming the PD isolation pattern 150 according to the present example embodiment may be performed after various pixel circuit devices are formed on the first surface 110a of the substrate 110.

A substrate 110 may be a first conductivity-type (for example, a P-type) semiconductor substrate. A shallow trench isolation pattern 112, buried in a first surface 110a of the substrate 110, may be formed. In the shallow trench isolation pattern 112, an active region may be defined. Various pixel circuit devices, such as a transfer gate TG and a floating diffusion region FD, may be formed on the active region, on the first surface 110a of the substrate 110. The transfer gate TG may include a gate insulating film GI and a gate spacer SP. A cover insulating film 115 may be formed on the first surface 110a of the substrate 110 to cover the transfer gate TG, and then a portion of an inter-interconnection line insulating layer, that is, a first interlayer insulating layer 121a, may be formed. For example, the cover insulating film 115 may include silicon nitride, silicon oxynitride, or silicon carbide. For example, the first interlayer insulating layer 121a may include silicon oxide, silicon nitride, silicon oxynitride, or a low-κ material.

Subsequently, referring to FIG. 9B, a first isolation trench TR1, defining a pixel region PXR, may be formed on the substrate 100.

The first isolation trench TR may pass through the first interlayer insulating layer 121a, and may extend from the first surface 110a of the substrate 110 toward a second surface 110b of the substrate 110. The first isolation trench TR1 may be formed to be deeper than the shallow trench isolation pattern 112, and may pass through a portion of the shallow trench isolation pattern 112. The first isolation trench TR1 may be a deep trench having an aspect ratio of about 10:1 to about 15:1. A width of the first isolation trench TR1 may gradually decrease from the first surface 110a to the second surface 110b of the substrate 110. That is, the first isolation trench TR1 may have an inclined sidewall. A surface of the substrate 110 may be exposed to the inclined sidewall of the first isolation trench TR1. In the present example embodiment, the cover insulating film 115 may have an opening by the first isolation trench TR1.

Subsequently, referring to FIG. 9C, in the substrate 110, an insulating liner 151 and a polycrystalline semiconductor film 155P may be sequentially formed in the first isolation trench TR1, and a filling isolation layer 157 may be filled in the first isolation trench TR1.

The insulating liner 151 may be conformally formed on a sidewall of the first isolation trench TR1 and a surface of the first interlayer insulating layer 121a. For example, the insulating liner 151 may be formed using an atomic layer deposition (ALD) process. For example, the insulating liner 151 may include a silicon-based insulating material (for example, silicon nitride, silicon oxide, and/or silicon oxynitride), a high-κ material (for example, hafnium oxide and/or aluminum oxide), and/or a metal oxide.

The polycrystalline semiconductor film 155P may be conformally formed on the insulating liner 151. For example, the polycrystalline semiconductor film 155P may be polycrystalline silicon. The polycrystalline semiconductor film 155P is not limited to silicon, and may include germanium or silicon germanium. In one or more example embodiments, the polycrystalline semiconductor film 155P may be replaced with an amorphous semiconductor layer. For example, the amorphous semiconductor layer may include amorphous silicon, amorphous germanium, or amorphous silicon-germanium. The polycrystalline semiconductor film 155P may have a thickness, less than that of the insulating liner 151. The thickness of the polycrystalline semiconductor film 155P may be within a range of 20 Å to 370 Å.

The filling isolation layer 157 may be formed on the polycrystalline semiconductor film 155P to fill the first isolation trench TR1, and may be additionally formed on the first interlayer insulating layer 121a. The filling isolation layer 157 may include an insulating material, the same as or similar to that of the insulating liner 151. For example, the filling isolation layer 157 may include silicon oxide.

Subsequently, referring to FIG. 9D, the second isolation trench TR2 may be formed to expose the polycrystalline semiconductor film 155P.

The second isolation trench TR2 may be formed using an etch-back process. An upper region of the filling isolation layer 157 and an upper region of the polycrystalline semiconductor film 155P may be sequentially removed using the etch-back process. The second isolation trench TR2 may extend below the first surface 110a of the substrate 110, and may expose the polycrystalline semiconductor film 155P in the shallow trench isolation pattern 112.

Subsequently, referring to FIG. 9E, a metal layer 170 may be formed along surfaces of the polycrystalline semiconductor film 155P exposed by the second isolation trench TR2, and an annealing process may be applied to crystallize the polycrystalline semiconductor film 155P using the metal layer 170.

The present process may be performed by crystallizing the polycrystalline semiconductor film 155P using MIC. First, the metal layer 170 may be formed to be in contact with the polycrystalline semiconductor film 155P through a second isolation trench TR2. For example, the metal layer 170 may include Ni, Pd, Al, Ag, Cu, or Sn.

Subsequently, as a metal element of a metal layer S moves toward the second surface 110b of the substrate 110 in the polycrystalline semiconductor film 155P, using the annealing process (see arrow (M)), the polycrystalline semiconductor film 155P may be crystallized by the movement of the metal element. The annealing process may be performed at a relatively low temperature (400°C or less). For example, the annealing process may be performed within a range of 300°C to 600°C. As a result, a crystalline semiconductor film 155 may be obtained. The crystalline semiconductor film 155 may have single crystallinity or crystallinity close thereto (for example, a grain size of 100 nm or less).

Subsequently, referring to FIG. 9F, a desired first interlayer insulating layer may be formed by depositing an insulating material so as to fill the second isolation trench after a residual metal layer 170 is removed, and performing a planarization process.

The crystalline semiconductor film 155 may have single crystallinity or crystallinity close thereto (for example, a grain size of 100 nm or less). The crystalline semiconductor film 155 may have a small thickness to lower light absorption by the PD isolation pattern 150, thereby ensuring sufficient electrical conductivity. A portion of a metal element of the metal layer 170 may remain in the crystalline semiconductor film 155. For example, the crystalline semiconductor film 155 may include the metal element of the metal layer 170 in an amount of 0.2 at.% or less. For example, the metal element may include Ni, Pd, Al, Ag, Cu, or Sn.

A bottom region of the crystalline semiconductor film 155S, adjacent to the first surface 110a, may include a metal-semiconductor compound layer 155S. For example, the metal-semiconductor compound layer 155S may include a metal silicide. The metal silicide may be formed by a reaction between a metal moving from the metal layer 170 and a bottom region of the polycrystalline semiconductor film 155P. In the present example embodiment, the cover insulating film 115 may have an opening OP in which a region corresponding to the PD isolation pattern 150 is open.

Subsequently, referring to FIG. 9G, the second surface 110b of the substrate 110 may be polished to expose the pixel isolation pattern 150 after a first interconnection line structure 120 including a contact via 125V is formed.

The first interconnection line structure 120 illustrated in FIG. 5 may be formed on the first surface 110a of the substrate 110. Subsequently, in the present example embodiment, the second surface 110b of the substrate 110 may be polished using a chemical mechanical polishing (CMP) process. In the present example embodiment, the polished second surface 110b of the substrate 110 may be provided as a light incident surface. In the process of polishing the second surface 110b of the substrate 110, the metal-semiconductor compound layer 155S of the crystalline semiconductor film 155 may be removed. In one or more example embodiments, the metal-semiconductor compound layer 155S may remain in an end portion of the PD isolation pattern 150, adjacent to the second surface 110b.

In the present example embodiment, a doping process may be additionally applied to the polycrystalline semiconductor film 155P or the crystalline semiconductor film 155. For example, the doping process may include a beamline ion implantation process or a plasma doping process PLAD.

Unlike the previous example embodiment, before various pixel circuit devices are formed on the first surface 110a of the substrate 110, the PD isolation pattern 150 having a crystalline silicon film 155 may be formed. FIGS. 10A to 10G are cross-sectional views of main processes in a method of manufacturing an image sensor according to an example embodiment of the present disclosure.

First, referring to FIG. 10A, a process of forming a PD isolation pattern 150 according to the present example embodiment may be performed after various pixel circuit devices are formed on a first surface 110a of a substrate 110.

A substrate 110 may be a first conductivity-type (for example, a P-type) semiconductor substrate. A shallow trench isolation pattern 112, buried in a first surface 110a of the substrate 110, may be formed. In the shallow trench isolation pattern 112, an active region may be defined.

Subsequently, referring to FIG. 10B, a first isolation trench TR1, defining a pixel region PXR, may be formed on the substrate 100.

The first isolation trench TR may pass through the shallow trench isolation pattern 112, and may extend from the first surface 110a of the substrate 110 toward a second surface 110b of the substrate 110. A width of the first isolation trench TR1 may gradually decrease from the first surface 110a to the second surface 110b of the substrate 110. That is, the first isolation trench TR1 may have an inclined sidewall. A surface of the substrate 110 may be exposed to the inclined sidewall of the first isolation trench TR1.

Subsequently, referring to FIG. 10C, in the substrate 110, an insulating liner 151 and a polycrystalline semiconductor film 155P may be sequentially formed in the first isolation trench TR1, and a filling isolation layer 157 may be filled in the first isolation trench TR1.

The insulating liner 151 may be conformally formed on the sidewall of the first isolating trench TR1 and the first surface 110a of the first substrate. For example, the insulating liner 151 may be formed using an atomic layer deposition (ALD) process. For example, the insulating liner 151 may include a silicon-based insulating material (for example, silicon nitride, silicon oxide, and/or silicon oxynitride), a high-κ material (for example, hafnium oxide and/or aluminum oxide), and/or a metal oxide.

The polycrystalline semiconductor film 155P may be conformally formed on the insulating liner 151. For example, the polycrystalline semiconductor film 155P may be polycrystalline silicon. In one or more example embodiments, the polycrystalline semiconductor film 155P may be replaced with an amorphous semiconductor layer. For example, the amorphous semiconductor layer may include amorphous silicon, amorphous germanium, or amorphous silicon-germanium. The polycrystalline semiconductor film 155P may have a thickness, less than that of the insulating liner 151. The thickness of the polycrystalline semiconductor film 155P may be within a range of 20 Å to 370 Å.

The filling isolation layer 157 may be formed on the polycrystalline semiconductor film 155P to fill the first isolation trench TR1, and may be additionally formed on a first interlayer insulating layer 121a. The filling isolation layer 157 may include an insulating material, the same as or similar to that of the insulating liner 151. For example, the filling isolation layer 157 may include silicon oxide.

Subsequently, referring to FIG. 10D, the second isolation trench TR2 may be formed to expose the polycrystalline semiconductor film 155P.

The second isolation trench TR2 may be formed using an etch-back process. An upper region of the filling isolation layer 157 and an upper region of the polycrystalline semiconductor film 155P may be sequentially removed using the etch-back process. The second isolation trench TR2 may extend below the first surface 110a of the substrate 110, and may expose the polycrystalline semiconductor film 155P in the shallow trench isolation pattern 112.

Subsequently, referring to FIG. 10E, a metal layer 170 may be formed along surfaces of the polycrystalline semiconductor film 155P exposed by the second isolation trench TR2, and an annealing process may be applied to crystallize the polycrystalline semiconductor film 155P using the metal layer 170.

In a similar manner to the previous example embodiment, the polycrystalline semiconductor film 155P may be crystallized using MIC. First, the metal layer 170 may be formed to be in contact with the polycrystalline semiconductor film 155P through the second isolation trench TR2. For example, the metal layer 170 may include Ni, Pd, Al, Ag, Cu, or Sn.

Subsequently, a metal element of a metal layer S may move toward the second surface 110b of the substrate 110 in the polycrystalline semiconductor film 155P, using the annealing process (see arrow (M)). As a result, a crystalline semiconductor film 155 may be obtained. The crystalline semiconductor film 155 may have single crystallinity or crystallinity close thereto (for example, a grain size of 100 nm or less).

Subsequently, referring to FIG. 10F, the shallow trench isolation pattern 112 may be formed by depositing an insulating material so as to fill the second isolation trench after a residual metal layer 170 is removed, and performing a planarization process.

The crystalline semiconductor film 155 may have single crystallinity or crystallinity close thereto (for example, a grain size of 100 nm or less). The crystalline semiconductor film 155 may have a small thickness to lower light absorption by the PD isolation pattern 150, thereby ensuring sufficient electrical conductivity. A portion of a metal element of the metal layer 170 may remain in the crystalline semiconductor film 155. For example, the crystalline semiconductor film 155 may include the metal element of the metal layer 170 in an amount of 0.2 at.% or less. For example, the metal element may include Ni, Pd, Al, Ag, Cu, or Sn.

A bottom region of the crystalline semiconductor film 155S, adjacent to the first surface 110a, may include a metal-semiconductor compound layer 155S. For example, the metal-semiconductor compound layer 155S may include a metal silicide. The metal silicide may be formed by a reaction between a metal moving from the metal layer 170 and a bottom region of the polycrystalline semiconductor film 155P.

Subsequently, referring to FIG. 10G, the second surface 110b of the substrate 110 may be polished to expose the pixel isolation pattern 150 after pixel circuit devices and a first interconnection line structure 120 are formed.

After the pixel isolation pattern is formed using the series of processes described above, the pixel circuit devices may be formed on the first surface 110a of the substrate 110, such as a transfer gate TG and a floating diffusion region FD, on the active region. A cover insulating film 115 may be formed on the first surface 110a of the substrate 110 to cover the transfer gate TG. Subsequently, the first interconnection line structure 120 may be formed.

In addition, in the present example embodiment, the second surface 110b of the substrate 110 may be polished using a CMP process. In the process of polishing the second surface 110b of the substrate 110, the metal-semiconductor compound layer 155S of the crystalline semiconductor film 155 may be removed. In one or more example embodiments, the metal-semiconductor compound layer 155S may remain in an end portion of the PD isolation pattern 150, adjacent to the second surface 110b.

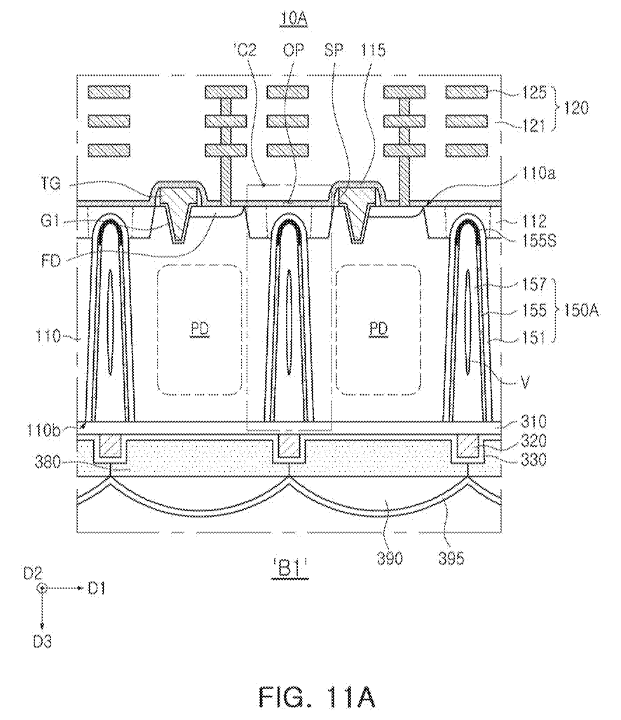

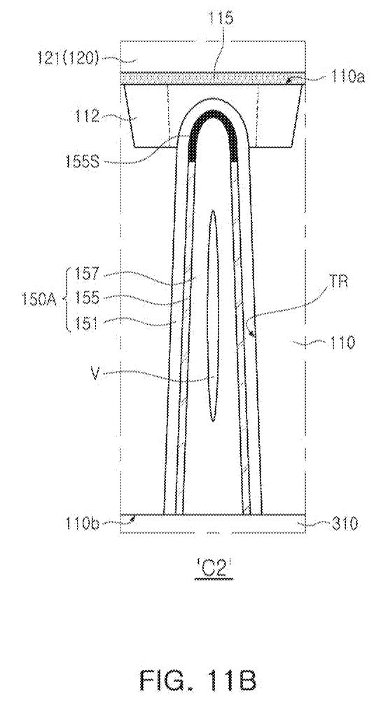

FIG. 11A is a side cross-sectional view of an image sensor according to an example embodiment of the present disclosure, and FIG. 11B is an enlarged view of portion “C2” in FIG. 11A.

Referring to FIGS. 11A and 11B, an image sensor 10A according to the present example embodiment may be understood to have a structure similar to that of the image sensor 10 illustrated in FIGS. 1 to 6, except that a PD isolation pattern 150A extends from a second surface 110b to a first surface 110a of a substrate 110 and a metal-semiconductor compound layer 155S is formed on one end of a crystalline semiconductor film 155. In addition, components of the present example embodiment may be understood with reference to descriptions of the same or similar components of the image sensor 10 illustrated in FIGS. 1 to 6, unless otherwise stated.

Unlike previous example embodiments, the PD isolation pattern 150A according to the present example embodiment may have a width gradually decreasing from the second surface 110b to the first surface 110a of the substrate 110. The PD isolation pattern 150 may include an insulating liner 151 disposed on an inner wall and a bottom of a PD isolation trench TRa, a crystalline semiconductor film 155 disposed on the insulating liner 151, and a filling isolation layer 157 disposed on the crystalline semiconductor film 155 to fill the PD isolation trench TRa. In the present example embodiment, the filling isolation layer 157 may include a void V. The crystalline semiconductor film 155 may have a grain size of at least 100 nm. The crystalline semiconductor film 155 may include a semiconductor material doped with impurities. The crystalline semiconductor film 155 may include a metal element in an amount of 0.2 at% or less. For example, the crystalline semiconductor film 155 may include Ni, Pd, Al, Ag, Cu, or Sn.

The crystalline semiconductor film 155 may have a bottom portion positioned at the bottom of the PD isolation trench TRa. In the present example embodiment, the bottom portion of the crystalline semiconductor film 155 may be adjacent to the first surface 110a of the substrate 110, and may be positioned in a shallow trench isolation pattern 112. The bottom portion of the crystalline semiconductor film 155 may include a metal-semiconductor compound layer 155S. For example, the metal-semiconductor compound 155S may include a metal silicide. A metal of the metal silicide may be the same as a metal element contained in the crystalline semiconductor film 155.

The image sensor 10 according to the present example embodiment may include a shallow trench isolation pattern 112, defining an active region of the substrate 110. However, in one or more example embodiments, the image sensor 10 may include another conductivity-type impurity region 110N in place of the shallow trench isolation pattern 112.

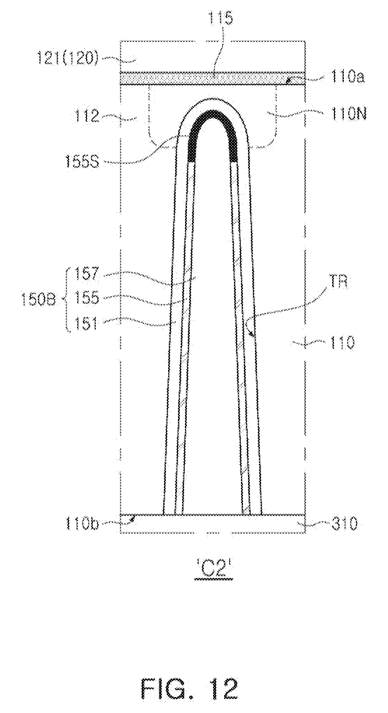

Referring to FIG. 12, an impurity region 110N may be included in a region of the substrate 110, adjacent to the first surface 110a. The impurity region 110N may include a conductivity-type (for example, N-type) impurity, different from a conductivity-type (for example, P-type) impurity, of the substrate 110. Unlike the previous example embodiment, the PD isolation pattern 150B according to the present example embodiment may extend from the second surface 110b of the substrate 110 toward the impurity region 110N adjacent to the first surface 110a. The crystalline semiconductor film 155 may have a bottom portion positioned at the bottom of the PD isolation trench TRa in the impurity region 110N. In the present example embodiment, the bottom portion of the crystalline semiconductor film 155 may include a metal-semiconductor compound layer 155S.

While one or more example embodiments have been shown and described above, it will be apparent to those skilled in the art that modifications and variations could be made without departing from the scope of the present disclosure as defined by the appended claims.

What is claimed is:

1. An image sensor comprising:
a substrate comprising a first surface and a second surface, wherein the second surface is on an opposite side of the substrate from the first surface, and wherein the substrate comprises a plurality of photodiode (PD) regions; and
a PD isolation pattern in a PD isolation trench in the substrate, wherein the PD isolation trench separates the plurality of PD regions,
wherein the PD isolation pattern comprises:
an insulating liner on an inner wall of the PD isolation trench;
a crystalline semiconductor film on the insulating liner, the crystalline semiconductor film comprising a grain size of at least 100 nm; and
a filling isolation layer on the crystalline semiconductor film, wherein the filling isolation layer fills the PD isolation trench.

2. The image sensor of claim 1, wherein the crystalline semiconductor film comprises silicon.

3. The image sensor of claim 2, wherein the crystalline semiconductor film comprises a metal in an amount less than or equal to 0.2 at%.

4. The image sensor of claim 3, wherein the metal comprises at least one of Ni, Pd, Al, Ag, Cu, or Sn.

5. The image sensor of claim 2, wherein the crystalline semiconductor film comprises a semiconductor material doped with an impurity.

6. The image sensor of claim 1, wherein a thickness of the insulating liner is greater than a thickness of the crystalline semiconductor film.

7. The image sensor of claim 6, wherein the thickness of the crystalline semiconductor film is in a range of 20 Å to 370 Å.

8. The image sensor of claim 1, wherein the filling isolation layer comprises an insulating material that is the same as a material of the insulating liner.

9. The image sensor of claim 1, further comprising:
a shallow trench isolation pattern on the first surface of the substrate,
wherein the shallow trench isolation pattern defines an active region, and
wherein the PD isolation trench passes through the shallow trench isolation pattern and extends from the first surface of the substrate to the second surface of the substrate.

10. The image sensor of claim 9, wherein the crystalline semiconductor film extends from below the shallow trench isolation pattern to the second surface of the substrate.

11. The image sensor of claim 9, wherein a portion of the crystalline semiconductor film, adjacent to the first surface, comprises a metal-semiconductor compound.

12. The image sensor of claim 1, wherein the PD isolation trench extends from the second surface of the substrate toward the first surface of the substrate, and
wherein a bottom of the PD isolation trench is positioned in a portion of the substrate adjacent to the first surface.

13. The image sensor of claim 12, wherein the crystalline semiconductor film comprises a portion extending on the bottom of the PD isolation trench, and the extending portion of the crystalline semiconductor film comprises a metal-semiconductor compound.

14. The image sensor of claim 1, wherein the filling isolation layer comprises a first isolation film on the crystalline semiconductor film, and a second isolation film on the first isolation film.

15. An image sensor comprising:
a substrate comprising a first surface and a second surface, wherein the second surface is on an opposite side of the substrate from the first surface, and wherein the substrate comprises a plurality of photodiode (PD) regions;
a shallow trench isolation pattern on the first surface of the substrate, wherein the shallow trench isolation pattern defines an active region;
a transfer gate on the active region; and
a PD isolation pattern extending from the shallow trench isolation pattern to the second surface of the substrate, wherein the PD isolation pattern is in a PD isolation trench and defines the plurality of PD regions,
wherein the PD isolation pattern comprises:
an insulating liner on an inner wall of the PD isolation trench;
a crystalline semiconductor film on the insulating liner, the crystalline semiconductor film having a grain size of at least 100 nm; and
a filling isolation layer on the crystalline semiconductor film, wherein the filling isolation layer fills the PD isolation trench.

16. The image sensor of claim 15, wherein the crystalline semiconductor film extends from below the shallow trench isolation pattern to the second surface of the substrate.

17. The image sensor of claim 16, wherein a thickness of the crystalline semiconductor film is within a range of 20 Å to 370 Å.

18. The image sensor of claim 15, further comprising:
a cover insulating film on the first surface of the substrate, the cover insulating film covering the transfer gate, and
wherein the cover insulating film has an opening in which a region corresponding to the PD isolation pattern is exposed.

19. An image sensor comprising:
a substrate comprising a first surface and a second surface, wherein the second surface is on an opposite side of the substrate from the first surface, and wherein the substrate comprises a plurality of photodiode (PD) regions;
a transfer gate on an active region of the first surface of the substrate; and
a PD isolation pattern in a PD isolation trench, the PD isolation pattern defining the plurality of PD regions,
wherein the PD isolation trench extends from the second surface of the substrate toward the first surface of the substrate, and has a bottom positioned in a portion of the substrate adjacent to the first surface, and
wherein the PD isolation pattern comprises:
an insulating liner on an inner wall and the bottom of the PD isolation trench;
a crystalline semiconductor film on the insulating liner, the crystalline semiconductor film having a grain size of at least 100 nm; and
a filling isolation layer on the crystalline semiconductor film, wherein the filling isolation layer fills the PD isolation trench.

20. The image sensor of claim 19, wherein the crystalline semiconductor film has a bottom portion positioned on the bottom of the PD isolation trench, and the bottom portion of the crystalline semiconductor film comprises a metal-semiconductor compound.
